(19) United States
(12) Patent Application Publication
(10) Pub. No.: US 2025/0077028 A1
(43) Pub. Date: Mar. 6, 2025

(54) METHOD OF TESTING DISPLAY APPARATUS, AND DISPLAY APPARATUS

(71) Applicant: Samsung Display Co., Ltd., Yongin-Si (KR)

(72) Inventors: Bongil Kang, Yongin-si (KR); Minhong Kim, Yongin-si (KR); Jungmok Park, Yongin-si (KR); Yerin Oh, Yongin-si (KR)

(21) Appl. No.: 18/823,684

(22) Filed: Sep. 4, 2024

(30) Foreign Application Priority Data
Sep. 5, 2023 (KR) 10-2023-0117937

(51) Int. Cl. G06F 3/041; G06F 3/044

(52) U.S. Cl. CPC G06F 3/04186; G06F 3/044

(57) ABSTRACT

A method of testing a display apparatus using a touch sensor and a touch integrated circuit is presented. The touch sensor includes a driving electrode line and a detection electrode line, and the touch integrated circuit includes a signal driving unit and a signal detection unit. The method includes sensing a first mutual capacitance of predetermined test coordinates by applying a first driving signal to the driving electrode line and receiving a detection signal from the detection electrode line, sensing a second mutual capacitance of the predetermined test coordinates by applying a second driving signal to the driving electrode line and receiving a detection signal from the detection electrode line, and determining whether a touch operation is performed based on a difference between the first mutual capacitance and the second mutual capacitance.

### CROSS-REFERENCE TO RELATED APPLICATION

This application is based on and claims priority under 35 U.S.C. § 119 to Korean Patent Application No. 10-2023-0117937 filed on Sep. 5, 2023 in the Korean Intellectual Property Office, the disclosure of which is incorporated by reference herein in its entirety.

### BACKGROUND

### 1. Field

One or more embodiments relate to a method of testing a display apparatus, and a display apparatus. More particularly, one or more embodiments relate to a method of testing a display apparatus, to determine whether a touch detection device is operating normally without directly touching a contact object, the method using a touch sensor, a touch integrated circuit, and a display apparatus.

### 2. Description of the Related Art

Recently, the usage of display apparatuses has diversified. As display apparatuses have become thinner and more lightweight, the range of uses thereof has widened.

Display apparatuses may include a touch detection device as an input apparatus. The touch detection device may include a touch sensor provided on the front side of the display apparatus, and a touch integrated circuit for driving the touch sensor and sensing a touch.

Known touch detection methods of touch detection devices include electromagnetic induction, pressure detection, capacitance, etc. In a capacitive touch detection device, when a touch sensor comes into contact with a contact object such as a human finger or stylus, the touch integrated circuit detects a change in capacitance of electrodes included in the touch sensor to determine whether a touch input has been received and the location of the touch.

### SUMMARY

When testing whether a touch detection device of a display apparatus is operating normally by directly touching the display apparatus with a finger, the accuracy of the test may vary depending on a size of the inspector's finger, degree of adhesion, etc. In one aspect, the present disclosure pertains to a method of testing a display apparatus to determine whether a touch detection device is operating normally without directly touching a contact object, by using a touch sensor and a touch integrated circuit, and a display apparatus. However, the one or more embodiments are only examples, and the scope of the disclosure is not limited thereto.

Additional aspects will be set forth in part in the description that follows and, in part, will be apparent from the description, or may be learned by practice of the embodiments of the disclosure.

According to one or more embodiments, a method of testing a display apparatus by using a touch sensor and a touch integrated circuit, wherein the touch sensor includes a driving electrode line and a detection electrode line, and wherein the touch integrated circuit includes a signal driving unit and a signal detection unit, may include sensing a first mutual capacitance of predetermined test coordinates by applying a first driving signal to the driving electrode line and receiving a detection signal from the detection electrode line, sensing a second mutual capacitance of the predetermined test coordinates by applying a second driving signal to the driving electrode line and receiving a detection signal from the detection electrode line, and determining whether a touch operation is performed based on a difference between the first mutual capacitance and the second mutual capacitance.

The second driving signal may be selected so that the second mutual capacitance according to the second driving signal has a value corresponding to a mutual capacitance corresponding to a direct touch of a contact object.

The signal driving unit may include a first switch and a second switch, which are selectively turned on and connect the signal driving unit and the driving electrode line to each other, and a test resistor connected to the driving electrode line by the second switch.

A driving signal generated by the signal driving unit may be transferred to the driving electrode line as the first driving signal, when the first switch is turned on, and may be transferred to the driving electrode line as the second driving signal, when the second switch is turned on.

A size of the test resistor may be selected so that the second mutual capacitance when the second switch is turned on has a value corresponding to a mutual capacitance when a contact object directly touches the display apparatus.

The test resistor may have a range of about 800Ω to about 1,200Ω.

The signal driving unit may include a charge pump configured to boost an input voltage and output the boosted voltage, and the first driving signal and the second driving signal may be adjusted according to a degree of boosting of the charge pump.

A second voltage corresponding to the second driving signal may be less than a first voltage corresponding to the first driving signal.

Each of the first voltage and the second voltage may have a range of about 3 V to about 6 V.

The driving electrode line may include driving electrodes arranged in a first direction, and first connection electrodes connecting the driving electrodes adjacent to each other in the first direction, and the detection electrode line may include detection electrodes arranged in a second direction crossing the first direction, and second connection electrodes connecting detection electrodes adjacent to each other in the second direction.

Each of the first mutual capacitance and the second mutual capacitance may be a capacitance between one of the first connection electrodes and one of the second connection electrodes that together define the predetermined test coordinates.

The driving electrode line may include a plurality of driving electrode lines arranged apart from each other in the second direction, and the detection electrode line may include a plurality of detection electrode lines arranged apart from each other in the first direction.

According to one or more embodiments, a display apparatus includes a touch sensor including a driving electrode line and a detection electrode line, a touch integrated circuit including a signal driving unit and a signal detection unit, wherein the signal driving unit applies a driving signal to the driving electrode line, and the signal detection unit receives a detection signal from the detection electrode line, a control unit determines, through a variation in mutual capacitance between the driving electrode line and the detection electrode line, whether a touch is input, a plurality of switches configured to be selectively turned on according to a control signal of the control unit and connect the driving signal to the driving electrode line, and a test resistor is connected to the driving electrode line by at least one of the plurality of switches, wherein a size of the test resistor is selected so that a mutual capacitance generated when the test resistor is connected to the driving electrode line has a value corresponding to a mutual capacitance generated when a contact object directly touches the display apparatus.

The plurality of switches may be connected in parallel with each other.

The test resistor may have a range of about 800Ω to about 1,200Ω.

The plurality of switches may include a first switch and a second switch, the second switch connecting the test resistor to the driving electrode line.

The driving electrode line may include driving electrode units arranged in a first direction, and first connection electrodes connecting the driving electrode units adjacent to each other in the first direction, and the detection electrode line may include detection electrode units arranged in a second direction crossing the first direction, and second connection electrodes connecting detection electrode units adjacent to each other in the second direction.

In a plan view, each of the first connection electrodes may have at least a portion overlapping one of the second connection electrodes.

The driving electrode line may include a plurality of driving electrode lines apart from each other in the second direction, and the plurality of driving electrode lines may be connected to the plurality of switches, respectively.

The display apparatus may further include a driving signal line connecting the signal driving unit and the driving electrode line to each other, and a detection signal line connecting the signal detection unit and the detection electrode line to each other.

These and/or other aspects will become apparent and more readily appreciated from the following description of the embodiments, the claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus according to an embodiment;

FIG. 2 is a cross-sectional view schematically illustrating a display apparatus according to one or more embodiments;

FIG. 3 is a block diagram schematically illustrating a display apparatus according to an embodiment;

FIG. 4 is an equivalent circuit diagram of a pixel included in a display apparatus, according to an embodiment;

FIG. 5 is a cross-sectional view schematically illustrating a cross-section of the display apparatus shown in FIG. 1, taken along line I-I′;

FIG. 6 is a diagram schematically illustrating a touch detection device included in a display apparatus, according to an embodiment;

FIGS. 7A, 7B, and 7C are plan views schematically illustrating a portion of a touch detection area;

FIG. 8 is a diagram for describing a sensing principle of a display apparatus according to an embodiment;

FIG. 9 is a diagram for describing a display apparatus and a sensing principle of the display apparatus, according to an embodiment;

FIGS. 10A and 10B are diagrams for describing a method of testing a display apparatus, according to an embodiment;

FIG. 11 is a diagram for describing a display apparatus and a method of testing the display apparatus, according to an embodiment;

FIGS. 12A and 12B are diagrams for describing test resistors of a display apparatus and a method of testing the display apparatus, according to an embodiment;

FIG. 13 is a diagram for describing a sensing principle of a display apparatus according to an embodiment; and

FIGS. 14A and 14B are diagrams for describing a display apparatus and a method of testing the display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Hereinafter, embodiments will be described with reference to the accompanying drawings, wherein like reference numerals refer to like elements throughout and a repeated description thereof is omitted.

In embodiments below, terms such as “first” and “second” are used herein merely to describe a variety of elements, but the elements are not limited by the terms. Such terms are used only for the purpose of distinguishing one element from another element.

In embodiments below, an expression used in the singular encompasses the expression of the plural, unless it has a clearly different meaning in the context.

Also, it will be understood that the terms “comprise,” “include,” and “have” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

When an embodiment may be implemented differently, a certain process order may be performed differently from the described order. For example, two consecutively described processes may be performed substantially at the same time or performed in an order opposite to the described order.

In the present specification, “A and/or B” means A or B, or A and B. In addition, “at least one of A and B” means A or B, or A and B.

It will be understood that when a layer, region, or element is referred to as being “connected,” the layer, the region, or the element may be directly connected and/or may be indirectly connected with intervening layers, regions, or elements therebetween. For example, it will be understood that when a layer, region, or element is referred to as being “electrically connected” to another layer, region, or element, it may denote “directly electrically connected” to the other layer, region, or element or may be “indirectly electrically connected” to other layer, region, and/or element with other layer, region, or element therebetween.

In the following disclosure, it will be understood that when a wire is referred to as “extending in a first direction or a second direction,” it may not only extend in a linear shape, but also may extend in the first direction or the second direction in a zigzag or curved line.

In embodiments described below, when referred to “in a plan view,” it means when an object is viewed from above, and when referred to “in a cross-sectional view,” it means when a cross section formed by vertically cutting an object is viewed from the side. In embodiments described below, when a first element “overlaps” a second element, it means that the first element is disposed over or under the second element.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

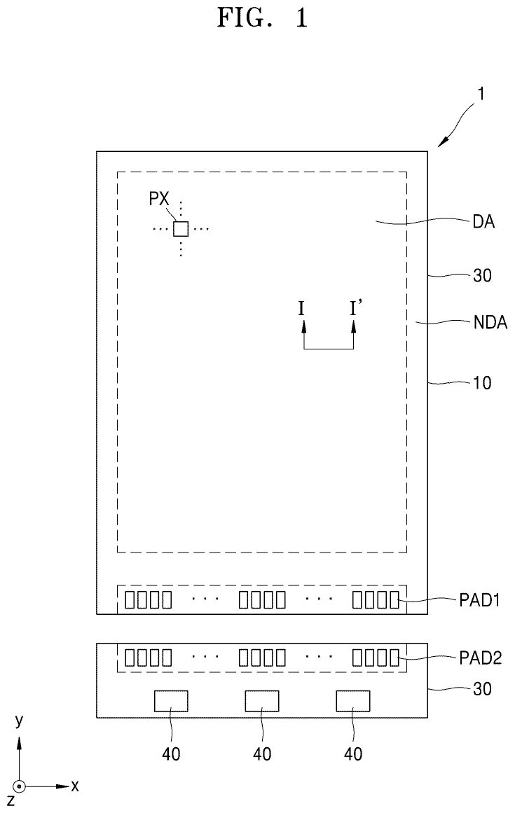

FIG. 1 is a plan view schematically illustrating a display apparatus 1 according to an embodiment.

Referring to FIG. 1, the display apparatus 1 may include a display panel 10 and a plurality of integrated circuits 40 for driving the display panel 10.

The display panel 10 may include a display area DA for implementing an image, and a non-display area NDA outside the display area DA. The display area DA may be entirely surrounded by the non-display area NDA.

In the display area DA of the display panel 10, pixels PX having various display elements such as organic light-emitting diodes may be arranged. The pixel PX may include a plurality of pixels, and the plurality of pixels PX may be arranged in various forms such as stripe arrangement, PENTILE™ arrangement, or mosaic arrangement, to implement an image.

In a plan view, the display area DA may be provided in a rectangular shape, as shown in FIG. 1. Alternatively, the display area DA may be provided in a polygonal shape such as a triangle, pentagon, or hexagon, or may be provided in a circular shape, elliptical shape, or amorphous shape.

The non-display area NDA of the display panel 10 is an area in which an image is not displayed, and may not have the pixels PX arranged therein. In the non-display area NDA, various lines configured to transmit electrical signals to be applied to elements arranged in the display area DA, driving circuits, and first pads PAD1 connected to the lines may be arranged.

Each of the plurality of integrated circuits 40 may be mounted on a circuit board 30. The plurality of integrated circuits 40 may be mounted on the circuit board 30 by using a chip on plastic (COP) method or a chip on glass (COG) method.

Lines connecting the plurality of integrated circuits 40 with second pads PAD2 may be disposed on the circuit board 30, and the plurality of integrated circuits 40 may be connected to the display panel 10 through the lines and the second pads PAD2.

Some of the plurality of integrated circuits 40 may generate electrical signals to be transferred to the plurality of integrated circuits 40 or driving circuits. Other circuits from among the plurality of integrated circuits 40 may generate electrical signals to be transferred to a driving electrode line and a detection electrode line.

The display apparatus 1 may be an organic light-emitting display including a display element that varies in brightness depending on current, for example, an organic light-emitting diode. Alternatively, the display apparatus 1 may be an inorganic light-emitting display (or an inorganic electroluminescent (EL) display) or quantum dot light-emitting display. In other words, an emission layer of the display element provided in the display apparatus 1 may include an organic material, an inorganic material, quantum dots, organic materials and quantum dots, inorganic material and quantum dots, or an organic material, an inorganic material, and quantum dots. Hereinafter, a case where the display apparatus 1 is an organic light-emitting display is mainly described.

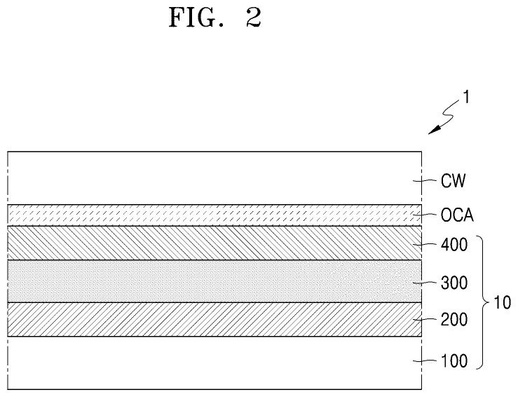

FIG. 2 is a cross-sectional view schematically illustrating a display apparatus 1 according to one or more embodiments.

Referring to FIG. 2, the display apparatus 1 may include the display panel 10 and a cover window CW covering the display panel 10.

The display panel 10 may include a substrate 100, a display element layer 200, an encapsulation layer 300, and a touch sensor layer 400.

The substrate 100 may include an insulating material such as glass, quartz, or polymer resin. The substrate 100 may be a rigid substrate, or a flexible substrate that is bendable, foldable, rollable, etc. For example, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure that includes a layer including the polymer resin described above, and an inorganic layer (not shown). For example, the substrate 100 may include two layers including the polymer resin described above, and an inorganic barrier layer located therebetween.

The display element layer 200 may be disposed on the substrate 100. The display element layer 200 includes pixels and may be a layer for displaying images. The display element layer 200 may include display elements and pixel circuits electrically connected to the display elements. In addition, the display element layer 200 may include scan lines, data lines, power lines, etc., connected to a pixel circuit, a scan driving unit for applying scan signals to the scan lines, a fan-out wirings for connecting the data lines with the display driving unit, etc.

The encapsulation layer 300 for sealing the display element may be disposed on the display element layer 200. The encapsulation layer 300 may include at least one organic encapsulation layer and provide a more flat base surface. Thus, even when the touch sensor layer 400 is formed by a continuous process, defect rates may be reduced.

The touch sensor layer 400 may be disposed on the encapsulation layer 300. The touch sensor layer 400 may include a touch sensor and signal lines connected to the touch sensor, and may be a layer for detecting whether a user's touch has been input, and the location of the touch. The touch sensor layer 400 may measure a change in capacitance of the driving electrodes and sensing electrodes included in the touch sensor and detect whether the user's touch has been input and the location of the touch by using a capacitance method.

The touch sensor layer 400 may be formed through a continuous process with the encapsulation layer 300, as shown in FIG. 2. For example, the touch sensor layer 400 may be formed directly on a base surface provided by the encapsulation layer 300.

In another embodiment, the touch sensor layer 400 may be provided as a separate functional module from the display panel 10 and arranged between the display panel 10 and the cover window CW. In this case, the touch sensor layer 400 may be coupled to the display panel 10 by using an optically clear adhesive (OCA) or optically clear resin.

The cover window CW may be disposed over the display panel 10. The cover window CW may function to protect the upper surface of the display panel 10. The cover window CW may be coupled to the display panel 10 by using an OCA or optically clear resin.

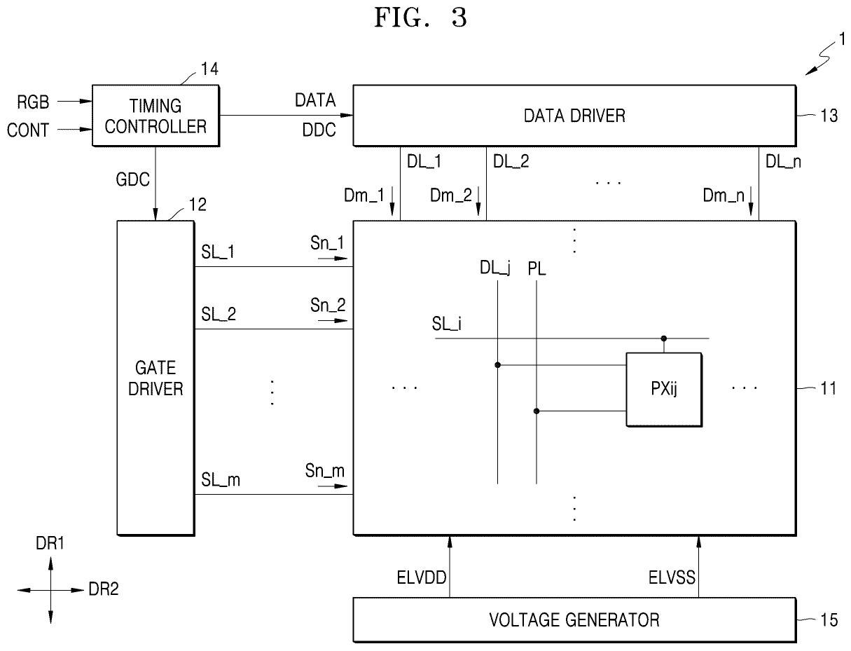

FIG. 3 is a block diagram schematically illustrating a display apparatus 1 according to an embodiment.

Referring to FIG. 3, the display apparatus 1 may include a display unit 11, a gate driver 12, a data driver 13, a timing controller 14, and a voltage generator 15.

The display unit 11 may include pixels PX, such as a pixel PXij located in the i-th row and j-th column. Although, for case of understanding, only one pixel PXij is shown in FIG. 3, m×n pixels PX may be arranged, for example, in a matrix form. Here, i is a natural number of m or less, and j is a natural number between 1 and n.

In FIG. 3, for illustrative purposes only, the description focuses on a pixel PX including two transistors and one capacitor. However, one or more embodiments is not only applied to the specific pixel circuit described above, but may also be equally applied to other pixel circuits, for example, a pixel PX employing a pixel circuit three transistors and one capacitor, a pixel PX employing a pixel circuit including seven transistors and one capacitor, etc.

The pixels PX may be connected to scan lines SL_1 to SL_m, data lines DL_1 to DL_n, and a power line PL. For example, the pixel PXij located in the i-th row and j-th column may be connected to the scan line SL_1, the data line DL_j, and the power line PL.

The data lines DL_1 to DL_n may extend in a first direction (or column direction) DR1 and may be connected to the pixels PX located in the same column. The scan lines SL_1 to SL_m may extend in a second direction (or row direction) DR2 and may be connected to the pixels PX located in the same row.

The power line PL may include a plurality of vertical power lines extending in the first direction DR1, and the plurality of vertical power lines may be connected to the power line PL located in the same column. The power line PL may include a plurality of horizontal power lines extending in the second direction DR2, and the plurality of horizontal power lines may be connected to the power line PL located in the same row. The plurality of horizontal power lines and the plurality of vertical power lines may be connected to each other.

Each of the scan lines SL_1 to SL_m may transfer scan signals Sn_1 to Sn_m output from the gate driver 12 to the pixels PX in the same row. Each of the data lines DL_1 to DL_n may transfer data signals Dm_1 to Dm_n output from the data driver 13 to the pixels PX in the same column. The pixel PXij located in the i-th row and j-th column may receive the scan signal Sn_i and the data signal Dm_j.

The power line PL may transfer a first driving voltage ELVDD output from the voltage generator 15 to the pixels PX.

The pixel PXij may include a display element and a driving transistor configured to control an amount of current flowing to the display element based on the data signal Dm_j. The data signal Dm_j may be output from the data driver 13 and received in the pixel PXij through the data line DL_j. For example, the display element may be an organic light-emitting diode. The data signal Dm_j emits light with a brightness corresponding to the amount of current received from the driving transistor, to express a grayscale corresponding to the data signal Dm_j. The pixel PX may correspond to a portion of a unit pixel capable of displaying full color, for example, a sub-pixel. The pixel PXij may include at least one switching transistor and at least one capacitor.

The voltage generator 15 may generate voltages necessary for driving the pixel PXij. For example, the voltage generator 15 may generate the first driving voltage ELVDD and a second driving voltage ELVSS. A level of the first driving voltage ELVDD may be higher than a level of the second driving voltage ELVSS.

The voltage generator 15 may generate an initialization voltage and provide the voltage to the pixels PX. The initialization voltage may be applied to a gate of a driving transistor and/or an anode of a display element.

In addition, the voltage generator 15 may generate a turn-on voltage and a turn-off voltage, which are for controlling a switching transistor of the pixel PXij, and provide the voltages to the gate driver 12. When the turn-on voltage is applied to a gate of the switching transistor, the switching transistor is turned on, and when the turn-off voltage is applied to the gate of the switching transistor, the switching transistor may be turned off. The voltage generator 15 may generate gamma reference voltages and provide the voltages to the data driver 13.

The timing controller 14 may control the gate driver 12 and operation timing of the data driver 13, to control the display unit 11. The pixels PX of the display unit 11 may receive a new data signal Dm every frame period and emit light with a luminance corresponding to the data signal Dm, to display an image corresponding to image source data RGB of one frame.

The timing controller 14 may receive the image source data RGB and a control signal CONT from the outside. The timing controller 14 may convert the image source data RGB into image data DATA based on characteristics of the display unit 11 and the pixels PX. The timing controller 14 may provide the image data DATA to the data driver 13.

The control signal CONT may include a vertical synchronization signal, a horizontal synchronization signal, a data enable signal, a clock signal, etc. The timing controller 14 may control the gate driver 12 and the operation timing of the data driver 13 by using the control signal CONT. The timing controller 14 may determine a frame period by counting data enable signals of a horizontal scanning period. In this case, a vertical synchronization signal and a horizontal synchronization signal, supplied from the outside, may be omitted. The image source data RGB may include luminance information of the pixels PX. The luminance may have a set number of gray levels, for example, 1024 (=2¹⁰), 256 (=2⁸), or 64 (=2⁶).

The timing controller 14 may generate control signals including a gate timing control signal GDC for controlling an operation timing of the gate driver 12, and a data timing control signal DDC for controlling the operation timing of the data driver 13.

The gate timing control signal GDC may include a gate start pulse, a gate shift clock, a gate output enable signal, etc. The gate start pulse may be supplied to the gate driver 12, which generates a first scan signal at a starting point of a scanning period. The gate shift clock is a clock signal commonly input to the gate driver 12 and may be a clock signal for shifting a gate start pulse. The gate output enable signal may control an output of the gate driver 12.

The data timing control signal may include a source start pulse, a source sampling clock, a source output enable signal, etc. The source start pulse may control a starting time point of data sampling of the data driver 13 and may be provided to the data driver 13 at a starting time point of a scanning period. The source sampling clock may be a clock signal for controlling a sampling operation of data within the data driver 13 based on rising or falling edges. The source output enable signal may control the output of the data driver 13. Meanwhile, the source start pulse supplied to the data driver 13 may be omitted depending on a data transmission method.

In response to the gate timing control signal GDC supplied from the timing controller 14, the gate driver 12 may sequentially provide the scan signals Sn_1 to Sn_m by using a turn-on voltage or turn-off voltage provided from the voltage generator 15. The gate driver 12 may include a plurality of transistors and may be formed together with the pixels PX through a thin film process. For example, the gate driver 12 may be mounted on the non-display area NDA in the form of an amorphous silicon TFT gate driver circuit (ASG) or an oxide semiconductor TFT gate driver circuit (OSG).

In response to the data timing control signal DDC supplied from the timing controller 14, the data driver 13 may sample and latch the image data DATA supplied from the timing controller 14 and convert the data into data in a parallel data system. When performing conversion into data in a parallel data system, the data driver 13 may convert the image data DATA into a gamma reference voltage, and convert the gamma reference voltage into an analog data signal. The data driver 13 may provide the data signals Dm_1 to Dm_n to the pixels PX through the data lines DL_1 to DL_n. The pixels PX may receive the data signals Dm_1 to Dm_n in response to the scan signals Sn_1 to Sn_m.

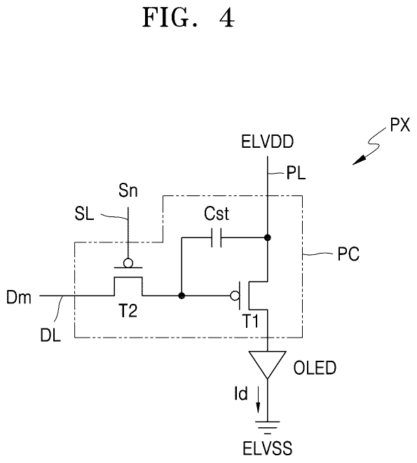

FIG. 4 is an equivalent circuit diagram of a pixel PX included in a display apparatus, according to an embodiment.

Referring to FIG. 4, the pixel PX may include a pixel circuit PC connected to a scan line SL and a data line DL, and a display element connected to the pixel circuit PC. The display element may be an organic light-emitting diode OLED, which includes a pixel electrode (anode) and an opposite electrode (cathode). The opposite electrode of the organic light-emitting diode OLED may be a common electrode to which the second driving voltage ELVSS is applied.

The pixel circuit PC may include a first transistor T1, a second transistor T2, and a storage capacitor Cst.

The first transistor T1 may be a driving transistor in which a size of drain current is determined according to a gate-source voltage, and the second transistor T2 may be a switching transistor, which is turned on or off according to the gate-source voltage, substantially, a gate voltage. The first transistor T1 and the second transistor T2 may be formed as thin-film transistors.

The first transistor T1 may be referred to as a driving transistor, and the second transistor T2 may be referred to as a scan transistor.

The storage capacitor Cst may be connected to the power line PL and a gate of the first transistor T1. The storage capacitor Cst may have a second electrode connected to the power line PL, and a first electrode connected to the gate of the first transistor T1. The storage capacitor Cst may store a voltage corresponding to a voltage difference between a voltage received from the second transistor T2 and the first driving voltage ELVDD supplied to the power line PL.

The first transistor T1 may control a size of driving current Id flowing from the power line PL to the organic light-emitting diode OLED according to the gate-source voltage. The organic light-emitting diode OLED may emit light with a certain luminance according to the driving current Id. The first transistor T1 may include a gate connected to a first electrode of the storage capacitor Cst, a first terminal connected to the power line PL, and a second terminal connected to the organic light-emitting diode OLED.

The second transistor T2 may transfer the data signal Dm to the gate of the first transistor T1 in response to a scan signal Sn. The second transistor T2 may include a gate connected to the scan line SL, a drain connected to the data line DL, and a source connected to the gate of the first transistor T1.

In FIG. 4, the pixel circuit PC includes two transistors and one storage capacitor. However, one or more embodiments are not limited thereto. For example, the pixel circuit PC may include three or more transistors and/or two or more storage capacitors. In an embodiment, the pixel circuit PC may include three transistors and one storage capacitor. In another embodiment, the pixel circuit PC may include seven transistors and one storage capacitor.

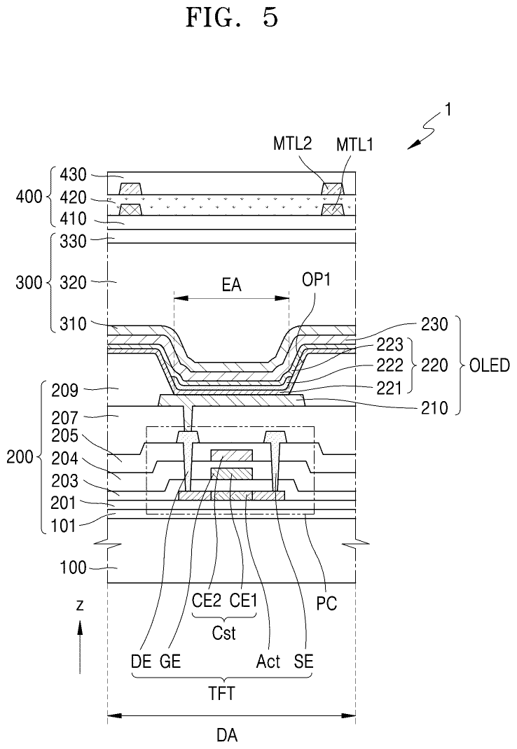

FIG. 5 is a cross-sectional view schematically illustrating a cross-section of the display apparatus 1 shown in FIG. 1, taken along line I-I′.

Referring to FIG. 5, the display element layer 200, the encapsulation layer 300, and the touch sensor layer 400 may be sequentially stacked on the display area DA of the substrate 100. The organic light-emitting diode OLED and the pixel circuit PC electrically connected to the organic light-emitting diode OLED may be disposed on the display element layer 200.

As described with reference to FIG. 2, the substrate 100 may include insulating materials, such as glass, quartz, or polymer resin. The substrate 100 may be a rigid substrate, or a flexible substrate that is bendable, foldable, rollable, etc.

A buffer layer 201 may be disposed over the substrate 100 and may reduce or block permeation of foreign substances, moisture, or ambient air from a lower portion of the substrate 100 and provide a flat surface to a semiconductor layer Act. The buffer layer 201 may include an inorganic material, such as an oxide or nitride, an organic material, or an organic-inorganic composite, and may include a single-layered or multi-layered structure of an inorganic material and an organic material.

A barrier layer 101 may be further included between the substrate 100 and the buffer layer 201 to block permeation of ambient air. The buffer layer 201 and the barrier layer 101 may include silicon oxide (SiO₂) and/or silicon nitride (SiNₓ).

The pixel circuit PC including a thin-film transistor TFT and a storage capacitor Cst may be disposed on the buffer layer 201. The thin-film transistor TFT may correspond to the first transistor T1 described with reference to FIG. 4.

The thin-film transistor TFT may include the semiconductor layer Act, a gate electrode GE, a drain electrode DE, and a source electrode SE.

The semiconductor layer Act may be disposed on the buffer layer 201 and may include polysilicon. In another embodiment, the semiconductor layer Act may include amorphous silicon. In another embodiment, the semiconductor layer Act may include an oxide of at least one material selected from the group consisting of indium (In), gallium (Ga), stannum (Sn), zirconium (Zr), vanadium (V), hafnium (Hf), cadmium (Cd), germanium (Ge), chrome (Cr), titanium (Ti), and zinc (Zn). The semiconductor layer Act may include a channel region, a source region, and a drain region, wherein the source region and the drain region are doped with impurities. The source region and the drain region may be respectively arranged at opposite sides of the channel region.

A first gate insulating layer 203 may be provided to cover the semiconductor layer Act. The first gate insulating layer 203 may include an inorganic insulating material, such as SiO₂, SiNₓ, silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 203 may be a single layer or multi-layer including the inorganic insulating material described above.

The gate electrode GE may be disposed on the first gate insulating layer 203 to overlap the semiconductor layer Act. The gate electrode GE may include molybdenum (Mo), aluminum (Al), copper (Cu), Ti, and may include a single layer or multi-layer. For example, the gate electrode GE may be a single Mo layer.

A second gate insulating layer 204 may be provided to cover the gate electrode GE. The second gate insulating layer 204 may include an inorganic insulating material, such as SiO₂, SiNₓ, SiON, Al₂O₃, TiO₂, Ta₂O₅, HfO₂, or ZnO₂. The second gate insulating layer 204 may be a single layer or multi-layer including the inorganic insulating material described above.

A second electrode CE2 of the storage capacitor Cst may be disposed on the second gate insulating layer 204. The second electrode CE2 may overlap the gate electrode GE. The gate electrode GE and the second electrode CE2 may form the storage capacitor Cst by overlapping each other with the second gate insulating layer 204 therebetween. In other words, the gate electrode GE may function as a first electrode CE1 of the storage capacitor Cst.

The second electrode CE2 may include Al, platinum (Pt), palladium (Pd), silver (Ag), magnesium (Mg), gold (Au), nickel (Ni), neodymium (Nd), iridium (Ir), Cr, calcium (Ca), Mo, Ti, tungsten (W), and/or Cu, and may be a single layer or multi-layer of the materials described above.

An interlayer insulating layer 205 may be formed to cover the second electrode CE2. The interlayer insulating layer 205 may include SiO₂, SiNₓ, SiON, Al₂O₃, TiO₂, Ta₂O₅, HfO₂, ZnO₂, etc. The interlayer insulating layer 205 may be a single layer or multi-layer including the inorganic insulating material described above.

The buffer layer 201, the first gate insulating layer 203, the second gate insulating layer 204, and the interlayer insulating layer 205 may be collectively referred to as an inorganic insulating layer IIL.

The source electrode SE and the drain electrode DE may be disposed on the interlayer insulating layer 205. The source electrode SE and the drain electrode DE may include a conductive material, including Mo, Al, Cu, Ti, etc., and may be formed as a single layer or multi-layer including the materials described above. For example, the source electrode SE and the drain electrode DE may have a multi-layer structure of Ti/Al/Ti. In some embodiments, the source electrode SE or drain electrode DE may be omitted. For example, adjacent thin-film transistors TFT may share the source region or drain region of the semiconductor layer Act, and the source region or drain region may function as the source electrode SE or drain electrode DE, respectively.

A planarization insulating layer 207 may be disposed to cover the source electrode SE and the drain electrode DE. The planarization insulating layer 207 may provide a flat base surface to a pixel electrode 210 disposed thereon.

The planarization insulating layer 207 may include an organic material or inorganic material, and may have a single-layered structure or multi-layered structure. The planarization insulating layer 207 may include general-purpose polymers, such as benzocyclobutene (BCB), polyimide, hexamethyldisiloxane (HMDSO), polymethylmethacrylate (PMMA), or polystrene (PS), polymer derivatives having a phenol-based group, acryl-based polymers, imide-based polymers, aryl-ether-based polymers, amide-based polymers, fluorine-based polymers, p-xylene-based polymers, vinyl alcohol-based polymers, etc. The planarization insulating layer 207 may include an inorganic insulating material, such as SiO₂, SiNₓ, SiON, Al₂O₃, TiO₂, Ta₂O₅, HfO₂, or ZnO₂. When the planarization insulating layer 207 is formed, a layer may be formed, and then, chemical and mechanical polishing may be performed on the upper surface of the layer to provide a flat surface.

The pixel electrode 210 may be disposed on the planarization insulating layer 207. The planarization insulating layer 207 may have a via hole that exposes one of the source electrode SE and the drain electrode DE of the thin-film transistor TFT, and the pixel electrode 210 may be electrically connected to the thin-film transistor TFT by coming into contact with the source electrode SE or drain electrode DE via this hole.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including Ag, Mg, Al, Pt, Pd, Au, Ni, Nd, Ir, Cr, or any compounds thereof. For example, the pixel electrode 210 may have, over/under the reflective film described above, a structure having films including ITO, IZO, ZnO, or In₂O₃. In this case, the pixel electrode 210 may have a stacked structure of ITO/Ag/ITO.

A pixel-defining layer 209 may cover edges of the pixel electrode 210 on the planarization insulating layer 207, and may have a pixel opening OP that exposes a central portion of the pixel electrode 210. An emission area of the organic light-emitting diode OLED, that is, a size and shape of the pixel, may be defined by the pixel opening OP.

The pixel-defining layer 209 may prevent an arc or the like from occurring at the edges of the pixel electrode 210 by increasing a distance between the edges of the pixel electrode 210 and an opposite electrode 230 of the pixel electrode 210. The pixel-defining layer 209 may be an organic insulating material, such as polyimide, polyamide, acrylic resin, BCB, HMDSO, and phenolic resin, and may be formed by a spin coating method or the like.

The pixel-defining layer 209 may be formed in black. This pixel-defining layer 209 includes a light-blocking material and may be provided in black. The light-blocking material may include carbon black, carbon nanotubes, resin or paste including black dye, metal particles, for example, Ni, Al, Mo, and any alloys thereof, metal oxide particles (for example, chrome oxide), metal nitride particles (for example, chrome nitride), etc. When the pixel-defining layer 209 includes a light-blocking material, outer reflection caused by metal structures disposed under the pixel-defining layer 209 may be reduced.

An intermediate layer 220 may be arranged between the pixel electrode 210 and the opposite electrode 230. The intermediate layer 220 may include a first functional layer 221, an emission layer 222, and a second functional layer 223.

The emission layer 222 formed to correspond to the pixel electrode 210 may be arranged in the pixel opening OP of the pixel-defining layer 209. The emission layer 222 may include a polymer material or low-molecular weight material, and may emit red, green, blue, or white light.

The first functional layer 221 and the second functional layer 223 may be disposed under and/or over the emission layer 222, respectively. In an embodiment, unlike the emission layer 222 that is patterned and arranged for each pixel, the first functional layer 221 and the second functional layer 223 may be integrally provided across the entire surface of the display area DA.

The first functional layer 221 may be a single layer or multi-layer. For example, when the first functional layer 221 includes a polymer material, the first functional layer 221 is a hole transport layer, which has a single-layered structure, and may include poly-(3,4)-ethylene-dihydroxy thiophene (PEDOT) or polyaniline (PANI). When the first functional layer 221 includes a low-molecular weight material, the first functional layer 221 may include a hole injection layer and a hole transport layer.

The second functional layer 223 may be selectively arranged. For example, when the first functional layer 221 and the emission layer 222 include a polymer material, it may be desirable to form the second functional layer 223. The second functional layer 223 may be a single layer or multi-layer. The second functional layer 223 may include an electron transport layer and/or electron injection layer. In some embodiments, at least one of a hole injection layer, a hole transport layer, an electron transport layer, and an electron injection layer may be omitted.

The opposite electrode 230 may include a conductive material having a relatively low work function. For example, the opposite electrode 230 may include a (semi-) transparent layer including Ag, Mg, Al, Ni, Cr, Li, Ca, or any alloys thereof. Alternatively, the opposite electrode 230 may further include a layer including ITO, IZO, ZnO, or In₂O₃, over the (semi-) transparent layer including the materials described above. In an embodiment, the opposite electrode 230 may include Ag and Mg.

A stacked structure of the pixel electrode 210, the intermediate layer 220, and the opposite electrode 230 that are sequentially stacked may form the opposite electrode 230.

In an embodiment, a capping layer (not shown) may be disposed on the organic light-emitting diode OLED. The capping layer may improve the emission efficiency of the organic light-emitting diode OLED by the principle of constructive interference. The capping layer may include an organic capping layer including an organic material, an inorganic capping layer including an inorganic material, or a composite capping layer including an organic material and an inorganic material.

The encapsulation layer 300 may be disposed on the organic light-emitting diode OLED. In an embodiment, the encapsulation layer 300 may include at least one inorganic encapsulation layer and at least one organic encapsulation layer. For example, the encapsulation layer 300 may include first and second inorganic encapsulation layers 310 and 330 and an organic encapsulation layer 320 located therebetween.

Each of the first and second inorganic encapsulation layers 310 and 330 may include one or more inorganic insulating materials. The inorganic insulating material may include Al₂O₃, TiO₂, Ta₂O₅, HfO₂, ZnO, SiOₓ, SiNₓ, and/or SiON. The first and second inorganic encapsulation layers 310 and 330 may be formed through chemical vapor deposition.

The organic encapsulation layer 320 may further include polyethylene terephthalate, polyethylene naphthalate, polycarbonate, polyimide, polyethylene sulfonate, polyoxymethylene, polyarylate, HMDSO, acryl-based resin, or any combinations thereof.

The encapsulation layer 300 covers the entire display area DA and may be arranged to extend to the non-display area NDA and cover at least a portion of the non-display area NDA.

As described above, the encapsulation layer 300 may include the organic encapsulation layer 320 and provide a more flat base surface. Thus, even when elements of the touch sensor layer 400 is formed by a continuous process, defect rates may be reduced.

The touch sensor layer 400 may have a multi-layered structure. The touch sensor layer 400 may include a detection electrode, a detection signal line connected to the detection electrode, a driving electrode, a driving signal line connected to the driving electrode, and at least one insulating layer. For example, a touch sensor included in the touch sensor layer 400 may detect an external input according to a capacitance method.

The touch sensor layer 400 may include a first touch insulating layer 410, a first touch conductive layer MTL1, a second touch insulating layer 420, a second touch conductive layer MTL2, and a third touch insulating layer 430.

The first touch insulating layer 410 may be disposed directly on the encapsulation layer 300. The first touch insulating layer 410 includes an inorganic material or organic material and may be provided as a single layer or multi-layer.

The first touch insulating layer 410 may prevent damage to the encapsulation layer 300 and block an interference signal that may occur when the touch sensor layer 400 is driven.

For example, each of the first touch conductive layer MTL1 and the second touch conductive layer MTL2 may have a single-layered structure or stacked multi-layered structure. A single-layer conductive layer may include a metal layer or transparent conductive layer. The metal layer may include Mo, Ag, Ti, Cu, Al, and any alloys thereof. The transparent conductive layer may include a transparent conductive oxide, such as ITO, IZO, ZnO, or ITZO. In addition, the transparent conductive layer may include conductive polymers, such as PEDOT, metal nanowires, graphene, etc.

A multi-layer conductive layer may include a plurality of metal layers. The plurality of metal layers may have, for example, a three-layer structure of Ti/Al/Ti. The multi-layer conductive layer may include at least one metal layer and at least one transparent conductive layer.

Each of the first touch conductive layer MTL1 and the second touch conductive layer MTL2 may include a plurality of patterns. It may be understood that the first touch conductive layer MTL1 includes first conductive patterns, and the second touch conductive layer MTL2 includes second conductive patterns. The first conductive patterns and the second conductive patterns may form a touch sensor.

The first touch conductive layer MTL1 and the second touch conductive layer MTL2 may be electrically connected to each other through a contact hole. In an embodiment, the first touch conductive layer MTL1 and the second touch conductive layer MTL2 may have a mesh structure so that light emitted from the organic light-emitting diode OLED may pass therethrough. In this case, the first touch conductive layer MTL1 and the second touch conductive layer MTL2 may be arranged not to overlap an emission area EA.

The second touch insulating layer 420 may include an organic material. The organic material may include at least one material selected from the group consisting of acryl-based resin, methacryl-based resin, polyisoprene, vinyl-based resin, epoxy-based resin, urethane-based resin, cellulose-based resin, and perylene-based resin. The second touch insulating layer 420 may further include an inorganic material. The inorganic material may include at least one material selected from the group consisting of SiNₓ, aluminum nitride (AlN), zirconium nitride (ZrN), titanium nitride (TiN), hafnium nitride (HfN), tantalum nitride (TaN), SiOₓ, Al₂O₃, TiO₂, tin oxide (SnO₂), cerium oxide (CeO₂), and SiON.

The third touch insulating layer 430 may be disposed on the second touch conductive layer MTL2. The third touch insulating layer 430 may have a single-layered or multi-layered structure. The third touch insulating layer 430 may include an organic material, inorganic material, or composite material.

In FIG. 5, the touch sensor layer 400 is formed directly on the encapsulation layer 300, and the display panel 10 (see FIG. 2) includes the touch sensor layer 400. However, one or more embodiments are not limited thereto. In another embodiment, the touch sensor layer 400 may be provided as a separate functional module from the display panel 10 and coupled to the display panel 10 by an OCA.

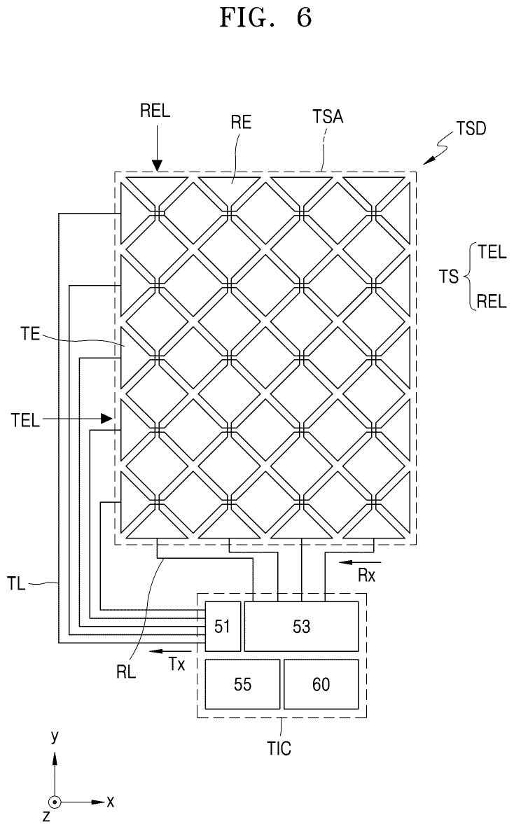

FIG. 6 is a diagram schematically illustrating a touch detection device TSD included in a display apparatus, according to an embodiment. Referring to FIG. 6, the touch detection device TSD may include a touch sensor TS arranged in a touch detection area TSA, and a touch integrated circuit TIC configured to control the touch sensor TS.

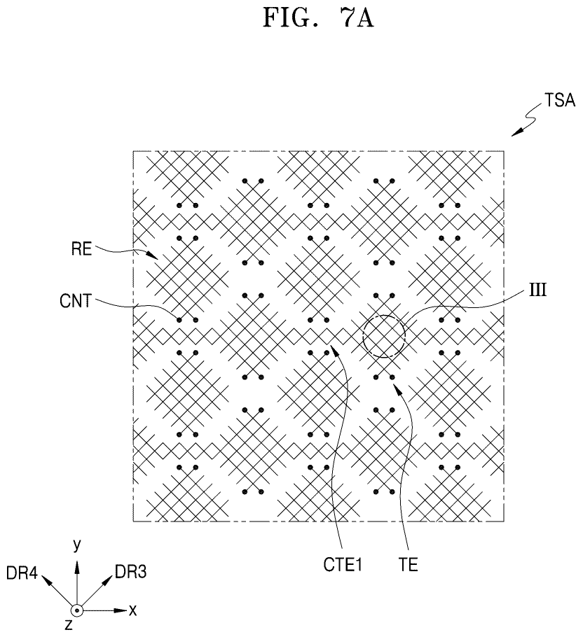

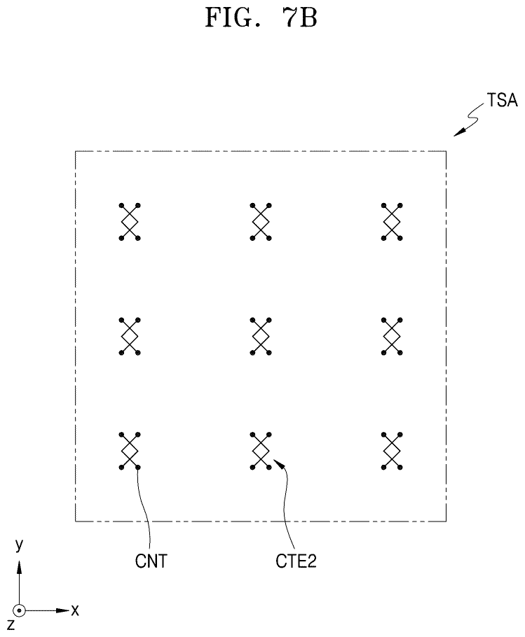

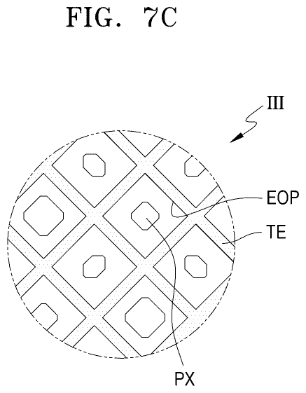

The touch sensor TS may include a driving electrode line TEL and a detection electrode line REL. The driving electrode line TEL may include a plurality of driving electrodes TE and a plurality of first connection electrodes CTE1 (see FIG. 7A), and the detection electrode line REL may include a plurality of detection electrodes RE and a plurality of second connection electrodes CTE2 (see FIG. 7B). The driving electrode line TEL may extend in a first direction (x direction), and the detection electrode line REL may extend in a second direction (y direction). The driving electrode line TEL and the detection electrode line REL may be arranged to cross each other in a plan view.

The driving electrode line TEL may include a plurality of driving electrode lines TEL, and the detection electrode line REL may include a plurality of detection electrode lines REL. The plurality of driving electrode lines TEL may be arranged apart from each other in the second direction (y direction), and the plurality of detection electrode lines REL may be arranged apart from each other in the first direction (x direction).

The touch integrated circuit TIC may correspond to at least one of the plurality of integrated circuits 40 shown in FIG. 1. In an embodiment, the touch integrated circuit TIC may be mounted on the circuit board 30 (see FIG. 1).

The touch integrated circuit TIC may include a signal driving unit 51, a signal detection unit 53, and a memory 55. The signal driving unit 51 may be electrically connected to the driving electrode lines TEL through driving signal lines TL and may apply a driving signal Tx to the driving electrode lines TEL. The signal detection unit 53 may be electrically connected to the detection electrode lines REL through detection signal lines RL and may receive a detection signal Rx from the detection electrode lines REL and convert the signal into a digital signal.

The signal detection unit 53 may include an analog front end AFE for receiving analog signals, and an analog digital converter ADC for converting an analog signal into a digital signal. The memory 55 may store software, algorithm, etc. for operating the touch integrated circuit TIC. The memory 55 may include random access memory (RAM) and/or flash memory.

A control unit 60 may control an operation of the touch integrated circuit TIC, and determine whether a touch input is received and the location of the touch based on detection signals received from the touch detection circuit TIC. The control unit 60 may include a microcontroller unit (MCU) and/or a central processing unit (CPU). In an embodiment, the control unit 60 may be included in the touch integrated circuit TIC. For example, as shown in FIG. 6, the touch integrated circuit TIC may be provided as a single chip including the control unit 60.

The touch integrated circuit TIC may sense a variation in mutual capacitance between the driving electrode line TEL and the detection electrode line REL, a variation in self-capacitance of the driving electrode line TEL, and/or a variation in self-capacitance of the detection electrode line REL. The touch integrated circuit TIC may generate a detection signal based on the variation in mutual capacitance and/or the variation in self-capacitance, and transfer the generated detection signal to the control unit 60. The control unit 60 may determine whether a touch input is received and the location of the touch based on the detection signal and control an operation mode of the touch integrated circuit TIC.

FIGS. 7A, 7B, and 7C are plan views schematically illustrating a portion of a touch detection area TSA. FIG. 7A shows the first touch conductive area MTL1 (see FIG. 5) arranged in the touch detection area TSA, and FIG. 7B shows the second touch conductive area MTL2 (see FIG. 5) arranged in the touch detection area TSA. FIG. 7C is an enlarged plan view illustrating region III in FIG. 7A.

Referring to FIGS. 7A and 7B, driving electrodes TE and detection electrodes RE, which are included in a touch sensor, may be arranged in the touch detection area TSA.

The driving electrodes TE may be arranged in the first direction (x direction) and the second direction (y direction). The driving electrodes TE adjacent to each other in the first direction (x direction) may be connected to each other by first connection electrodes CTE1 disposed on a first conductive layer. The driving electrodes TE and the first connection electrodes CTE1 may be integrally provided as a single body. The driving electrodes TE and the first connection electrodes CTE1 connected to each other in the first direction (x direction) may form the driving electrode line TEL (scc FIG. 6).

The detection electrodes RE may be arranged in the first direction (x direction) and the second direction (y direction). The detection electrodes RE adjacent to each other in the second direction (y direction) may be connected to each other by second connection electrodes CTE2 disposed on a second conductive layer. The second connection electrode CTE2 may be connected to the detection electrodes RE through a contact hole CNT. The detection electrodes RE and the second connection electrodes CTE2 connected to each other in the second direction (y direction) may form the detection electrode line REL (see FIG. 6).

Referring to FIGS. 7A and 7B together with FIG. 6, in a plan view, the driving electrode line TEL and the detection electrode line REL may be arranged to cross each other. For example, in a plan view, the first connection electrode CTE1 of the driving electrode line TEL and the second connection electrode CTE2 of the detection electrode line REL may be arranged to cross each other. Because an insulating layer (for example, a second touch insulating layer) is located between the first connection electrode CTE1 and the second connection electrode CTE2, the first connection electrode CTE1 and the second connection electrode CTE2 overlapping each other may form a kind of capacitor.

The driving electrodes TE and the detection electrodes RE may have a mesh (or grid, lattice) pattern. Metal patterns extending in a third direction DR3, the third direction DR3 crossing the first direction (x direction) and the second direction (y direction), and metal patterns extending in a fourth direction DR4 crossing the third direction DR3 may cross each other to form a mesh pattern. Accordingly, the driving electrodes TE and the detection electrodes RE may have a plurality of electrode openings. Likewise, the first connection electrode CTE1 and the second connection electrode CTE2 may have a mesh (or grid, lattice) pattern.

Referring to FIG. 7C, the driving electrode TE may have a mesh pattern. The driving electrode TE may define a plurality of electrode openings EOP located within a matrix of the mesh pattern. Each of the electrode openings EOP may be arranged to overlap one pixel PX. In other words, an emission area EA (see FIG. 5) of one pixel PX may be arranged inside each of the electrode openings EOP.

The detection electrode RE may have a mesh pattern similar to or identical to that of the driving electrode TE shown in FIG. 7C. Even when the driving electrodes TE and the detection electrodes RE include a metal layer, light emitted from the pixels PX may transmit the touch sensor layer (see FIG. 5) through the electrode openings EOP.

In an embodiment, unlike shown in FIGS. 7A and 7B, the driving electrodes TE, the first connection electrodes CTE1, and the detection electrodes RE are disposed on the second touch conductive layer MTL2 (see FIG. 5), and the second connection electrodes CTE2 may be disposed on the first touch conductive layer MTL1 (see FIG. 5). In an embodiment, the driving electrodes TE and the detection electrodes RE may have a surface pattern including a transparent conductive material.

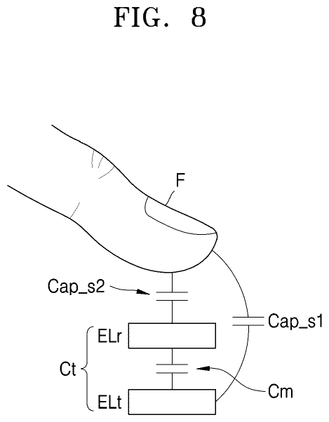

FIG. 8 is a diagram for describing a sensing principle of a display apparatus according to an embodiment.

Referring to FIG. 8, the touch sensor may include a touch capacitor Ct. The touch capacitor Ct may include a first electrode ELt and a second electrode ELr overlapping the first electrode ELt. For example, the first electrode ELt may correspond to one region of the driving electrode line TEL shown in FIG. 6, and the second electrode ELr may correspond to one region of the detection electrode line REL shown in FIG. 6. The first electrode ELt may correspond to the first connection electrode CTE1 (see FIG. 7A) of the driving electrode line, and the second electrode ELr may correspond to the second connection electrode CTE2 (see FIG. 7B) of the detection electrode line.

A mutual capacitance Cm may be generated between the first electrode ELt and the second electrode ELr overlapping each other in a plan view, with an insulating layer therebetween.

When a contact object F such as a finger or stylus is in contact with an upper surface of the touch capacitor Ct, the mutual capacitance Cm may change between the first electrode ELt and the second electrode ELr. The driving signal Tx (see FIG. 6) may be applied to the touch capacitor Ct through the driving signal line TL (see FIG. 6) electrically connected to the first electrode ELt, and the mutual capacitance Cm may be sensed by using the detection signal Rx (see FIG. 6) received through the detection signal line RL electrically connected to the second electrode ELr. Because a location of the touch capacitor Ct may be specified, whether a touch input is received and a touch location (touch coordinates) may be determined through a variation in mutual capacitance Cm.

When the contact object F is in contact with or adjacent to the upper surface of the touch capacitor Ct, a first self-capacitance Cap_s1 may be generated between the first electrode ELt and the contact object F. Likewise, a second self-capacitance Cap_s2 may be generated between the second electrode ELr and the contact object F. Based on a variation in first self-capacitance Cap_s1 or a variation in second self-capacitance Cap_s2, whether the contact object F is approaching and a touch input is received may be determined. The touch integrated circuit may sense a part or all of the mutual capacitance Cm, the first self-capacitance Cap_s1, and the second self-capacitance Cap_s2.

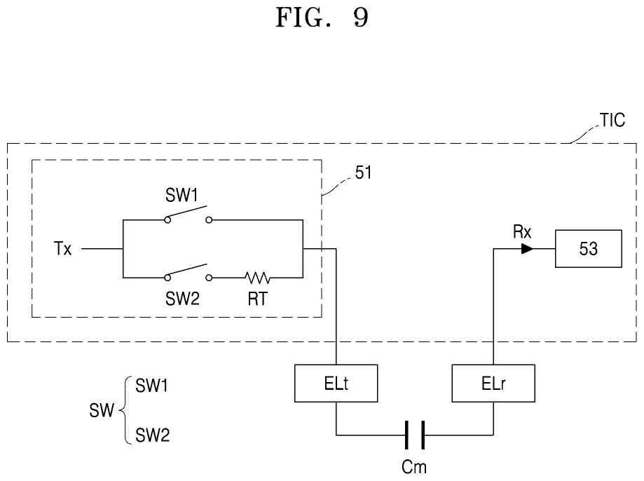

FIG. 9 is a diagram for describing a display apparatus and a sensing principle of the display apparatus according to an embodiment. The description is focused on a case where the first electrode ELt shown in the following drawings is a connection electrode of a driving electrode line, and the second electrode ELr is a second connection electrode of a detection electrode line. Hereinafter, applying a driving signal to a driving electrode line and applying a driving signal to the first electrode ELt may be understood to have substantially the same meaning.

A display apparatus according to an embodiment may include an touch integrated circuit TIC including a signal driving unit 51 and a signal detection unit 53, the signal driving unit S1 applying a driving signal Tx to a driving electrode line (or, first electrode ELt), and the signal detection unit 53 receiving a detection signal Rx from a detection electrode line (or, second electrode ELr), a plurality of switches SW connecting the driving signal Tx to the driving electrode line (or, first electrode ELt), and a test resistor RT connected to the driving electrode line (or, first electrode ELt) by at least one of the plurality of switches SW.

Referring to FIG. 9, the plurality of switches SW may be connected in parallel and may be included in the signal driving unit 51 of the touch integrated circuit TIC. The plurality of switches SW may be selectively turned on according to a control signal of the control unit 60 (see FIG. 6). In an embodiment, the plurality of driving electrode lines TEL (see FIG. 6) may be connected to the plurality of switches SW, respectively.

In an embodiment, the plurality of switches SW may include a first switch SW1 and a second switch SW2. The second switch SW2 may be connected to the test resistor RT, and when the second switch SW2 is turned on, the test resistor RT may be connected to the first electrode ELt. When the first switch SW1 is turned on, the driving signal Tx may be transferred to the first electrode ELt without passing through an additional test resistor, and when the second switch SW2 is turned on, the driving signal Tx may pass through the test resistor RT and may be converted into a certain test driving signal and transferred to the first electrode ELt.

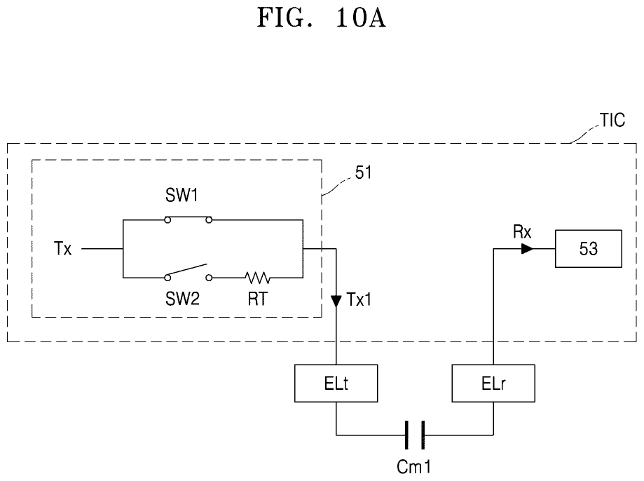

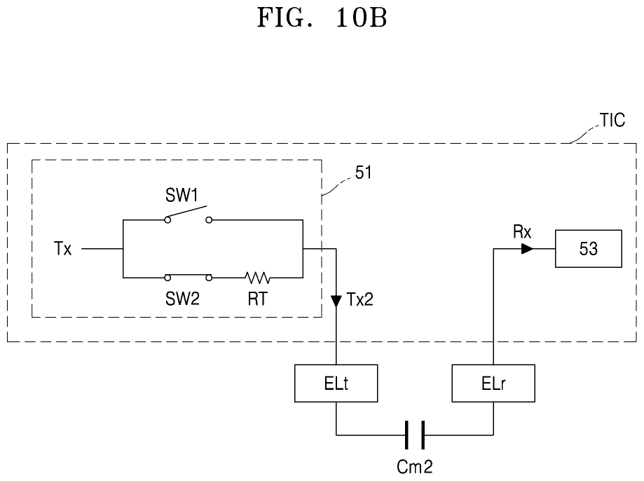

A size of the test resistor RT included in a display apparatus according to an embodiment may be selected such that a mutual capacitance Cm generated when at least one switch (in FIG. 9, the second switch SW2) connecting the test resistor RT to the first electrode ELt has a value corresponding to a mutual capacitance Cm generated when a user directly touches the display apparatus (for example, using a finger). As used herein, a value “corresponding to” a mutual capacitance Cm refers to a value that may be within 5% of the mutual capacitance Cm generated in the event of a direct touch. In other words, the size of the test resistor RT may be selected such that the mutual capacitance Cm generated when the test resistor RT is connected to the first electrode ELt has substantially the same value as the mutual capacitance Cm generated when a user directly touches the display apparatus. In an embodiment, the test resistor RT may range from 800Ω to 1,200Ω. Detailed descriptions thereof are provided below with reference to FIGS. 10A to 12B.

In general, when a test of whether a touch operation of a display device is performed, the test including a capacitive touch detection device, may be performed by allowing a contact object, such as a human finger, to be in contact with the touch sensor, and by detecting data before and after the finger touch (for example, a variation in capacitance), and whether a touch input is received at a predetermined test coordinate may be determined. In this case, because the data is affected by a size of a tester's finger, degree of adhesion, etc., the accuracy of the test may be unreliable and a considerable time may be consumed.

A method of testing a display apparatus, according to an embodiment, includes sensing a first mutual capacitance of a predetermined test coordinate by applying a first driving signal to a driving electrode line, sensing a second mutual capacitance of the predetermined test coordinate by applying a second driving signal to the driving electrode line, and determining whether a touch operation is performed by detecting a difference between the first mutual capacitance and the second mutual capacitance. The difference between the first mutual capacitance and the second mutual capacitance refers to a variation in mutual capacitance. The first mutual capacitance and the second mutual capacitance may be sensed by using a detection signal received from a detection signal line. Because whether a touch operation of the display apparatus may be tested without directly touching a contact object, the accuracy of the test may be improved and a time required for the test may be shortened. In addition, in a case of a method of applying a desired driving signal through switch operation control, switches that are built in may be used without adding a switch for testing.

FIGS. 10A and 10B are diagrams for describing a method of testing a display apparatus, according to an embodiment. As an example of a method of applying a first driving signal Tx1 or second driving signal Tx2, FIGS. 10A and 10B illustrate applying the first driving signal Tx1 and the second driving signal Tx2 to the first electrode ELt through switch control. The first electrode ELt and the second electrode ELr in FIGS. 10A and 10B may be electrodes corresponding to the predetermined test coordinate(s) to be tested. In FIGS. 10A and 10B, the same reference numerals as those of FIG. 9 denote the same member, and redundant descriptions thereof are omitted.

When the first switch SW1 is turned on and the second switch SW2 is turned off, as in FIG. 10A, the driving signal Tx of the signal driving unit 51 may be applied to the first electrode ELt as the first driving signal Tx1, and the first electrode ELt and the second electrode ELr may form a first mutual capacitance Cm1. The touch integrated circuit TIC may sense the first mutual capacitance Cm1 of the predetermined test coordinates through the detection signal Rx received by the signal detection unit 53.

When the first switch SW1 is turned off and the second switch SW2 is turned on, as in FIG. 10B, the driving signal Tx of the signal driving unit 51 may be applied to the first electrode ELt as the second driving signal Tx2, and the first electrode ELt and the second electrode ELr may form a second mutual capacitance Cm2. The touch integrated circuit TIC may sense the second mutual capacitance Cm2 of the predetermined test coordinates through the detection signal Rx received by the signal detection unit 53.

A difference between the first driving signal Tx1 and the second driving signal Tx2 may be implemented by a difference in size of a resistor connected to the first electrode ELt by the first switch SW1 and the second switch SW2. Unlike when the first switch SW1 is turned on, when the second switch SW2 is turned on, the test resistor RT is connected to the first electrode ELt, and thus, a difference may occur between the first mutual capacitance Cm1 and the second mutual capacitance Cm2.

The control unit 60 (see FIG. 6) may determine whether the predetermined test coordinates are touched through the difference between the first mutual capacitance Cm1 and the second mutual capacitance Cm2. When the difference between the first mutual capacitance Cm1 and the second mutual capacitance Cm2 is substantially the same as a variation of mutual capacitance generated when a touch object is directly touched.

When the touch detection device is normally operating, the first mutual capacitance Cm1 corresponds to a mutual capacitance in the absence of a touch, and the second mutual capacitance Cm2 may correspond to a mutual capacitance when a contact object is directly touched (for example, using a user's finger). To this end, the second driving signal Tx2 may be configured such that the second mutual capacitance Cm2 according to the second driving signal Tx2 has a value corresponding to a mutual capacitance according to a direct touch of the touch object. The size of the test resistor RT may be configured such that the second switch SW2 when the second switch SW2 is turned on has a value corresponding to a mutual capacitance according to a direct touch of the touch object.

In summary, the testing method according to an embodiment may include configuring the first driving signal Tx1 and the second driving signal Tx2 such that the first driving signal Tx1 corresponds to no-touch and the second driving signal Tx2 corresponds to direct touch, and sequentially applying the first driving signal Tx1 and the second driving signal Tx2 to the first driving signal Tx1 and detecting a difference in mutual capacitance. Whether a touch operation is normally detected may be determined based on whether the detected mutual capacitance difference is substantially the same as a variation in mutual capacitance obtained by allowing a contact object to be in direct contact.

In FIGS. 9, 10A, and 10B, there is one switch connecting a test resistor. However, an embodiment of the present disclosure is not limited thereto. For example, there may be two switches connecting a test resistor, and one of test resistors connected to each of the switches may be selected, or a plurality of the test resistors connected to each of the switches may be used in combination.

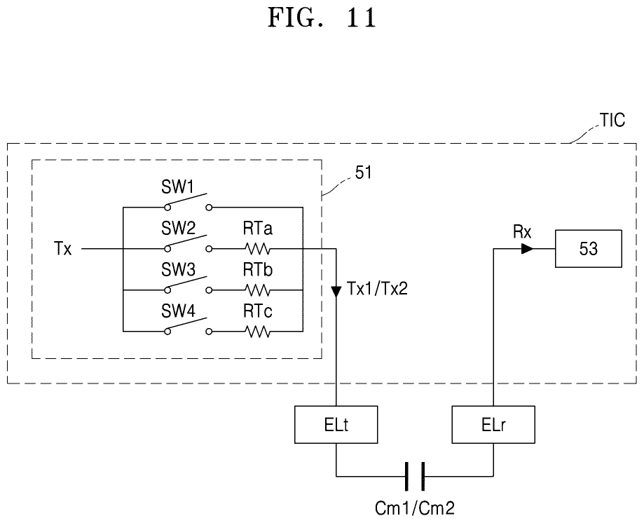

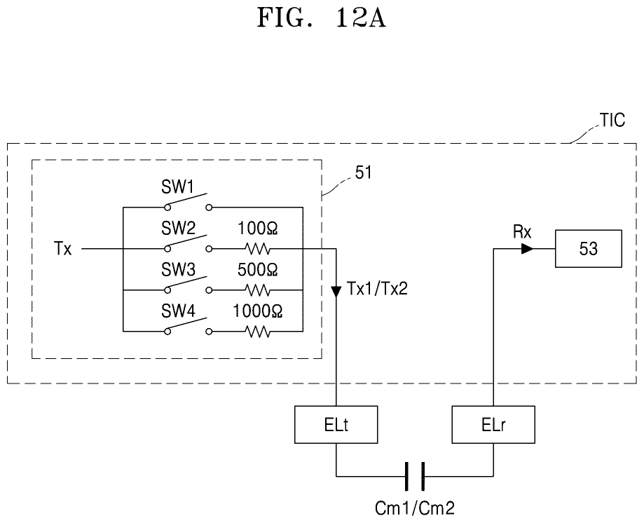

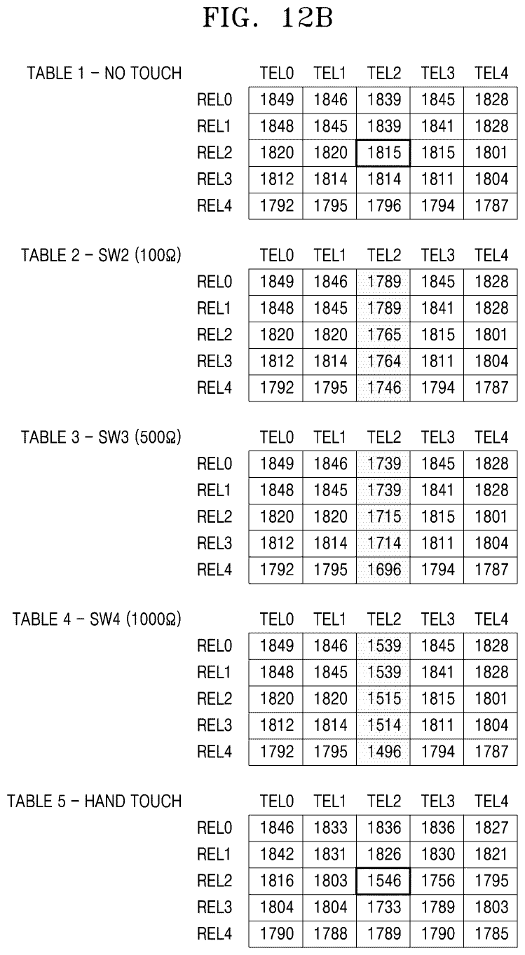

FIG. 11 is a diagram for describing a display apparatus and a method of testing a display apparatus, according to an embodiment, and FIGS. 12A and 12B are diagrams for describing test resistors of a display apparatus and a method of testing the display apparatus, according to an embodiment. In FIG. 11, the same reference numerals as those of FIG. 9 denote the same member, and redundant descriptions thereof are omitted.

Referring to FIG. 11, in an embodiment, the touch integrated circuit TIC may include three switches connecting test resistors. When at least one of a first switch SW1, a second switch SW2, a third switch SW3, and a fourth switch SW4 is turned on, the driving signal Tx of the signal driving unit 51 may be applied to the first electrode 29et as the first driving signal Tx1 or second driving signal Tx2. For example, when only the first switch SW1 is turned on, the first driving signal Tx1 may be applied to the first electrode 29et, and when only one of the second to fourth switches SW2, SW3, and SW4 is turned on, the second driving signal Tx2 may be applied to the first electrode 29et. In this case, a resistor connected to the turned-on switch may serve as a test resistor. Alternatively, when two or more switches from among the second to fourth switches SW2, SW3, and SW4 are turned on, the second driving signal Tx2 may be applied to the first electrode 29et, and in this case, an equivalent resistor of the connected resistors may serve as the test resistor.

Referring to FIG. 11, the second switch SW2 may be connected to a first test resistor Rta, the third switch SW3 may be connected to a second test resistor RTb, and the fourth switch SW4 may be connected to a third test resistor RTc. FIG. 12A shows an example in which a size of the first test resistor Rta is 100Ω, a size of the second test resistor RTb is 500Ω, and a size of the third test resistor RTc is 1,000Ω. FIG. 12B shows tables showing magnitudes of mutual capacitance of predetermined test coordinates (REL2, TEL2) and adjacent coordinates. The test coordinates (REL2, TEL2) may refer to an area in which a test detection electrode line REL2 and a test driving electrode line TEL2 overlap each other.

A signal driving unit connected to the plurality of driving electrode lines TEL0, TEL1, TEL2, TEL3, and TEL4 may include the switches and test resistors in the embodiment of FIG. 12A. Table 1 shows a no-touch state, and Table 5 shows a direct hand touch state at the test coordinates. Tables 1 and 5 show cases where none of the plurality of driving electrode lines TEL0, TEL1, TEL2, TEL3, and TEL4 is connected to a test resistor. Tables 2, 3, and 4 respectively show a mutual capacitance of each coordinate in a state in which a test resistor is connected to the test driving electrode line TEL2, and a test resistor is not connected to the other driving electrode lines TEL0, TEL1, TEL3, and TEL4. Table 2 shows a case where the test driving electrode line TEL2 is connected to the test resistor of 100Ω. Table 3 shows a case where the test driving electrode line TEL2 is connected to the test resistor of 500Ω. Table 4 shows a case where the test driving electrode line TEL2 is connected to the test resistor of 1,000Ω.

Referring mainly to the test coordinates (REL2, TEL2) in Tables 1 and 5, it may be seen that a size of mutual capacitance in these test coordinates changed from 1,815 during no touch to 1,546 in a case of hand touch. Looking at the values of the test coordinates (REL2, TEL2) in FIGS. 2 to 4, based on the above, among Tables 2 to 4, the case in FIG. 4 is 1,515, which is most similar to the size of mutual capacitance during hand touch in FIG. 5. This means that, when the resistor of 1,000Ω from among the resistors of 100Ω, 500Ω, and 1,000Ω is connected to the test driving electrode line TEL2, it is easier to proceed with a test by comparing the mutual capacitance during hand touch with the mutual capacitance through switch operation.

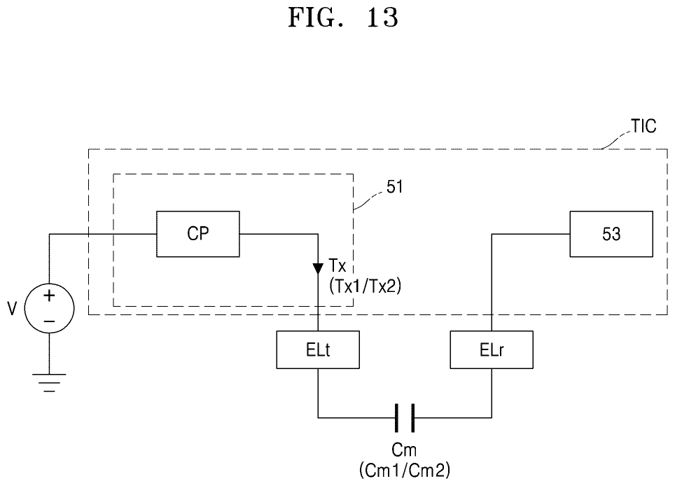

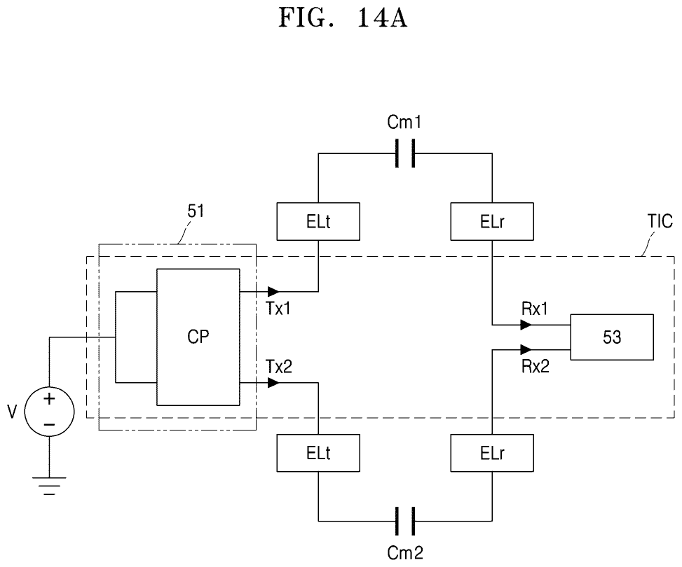

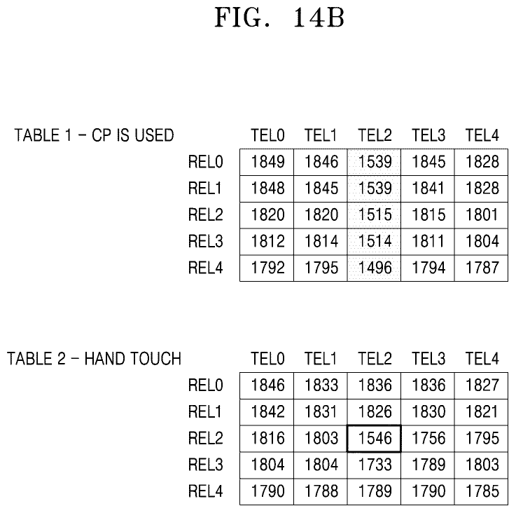

FIG. 13 is a diagram for describing a sensing principle of a display apparatus according to an embodiment, and FIGS. 14A and 14B are diagrams for describing a display apparatus and a method of testing the display apparatus, according to an embodiment. In FIG. 13, the same reference numerals as those of FIG. 9 denote the same member, and redundant descriptions thereof are omitted.

Referring to FIG. 13, the signal driving unit 51 may include a charge pump CP. The charge pump CP may boost an input voltage V applied to the signal driving unit 51 and output the voltage. In an embodiment, the signal driving unit 51 may receive a voltage of about 3 V, and the charge pump CP may boost the voltage to a voltage in the range of about 3 V to 6 V.

A method of testing a display apparatus, according to an embodiment, includes sensing the first mutual capacitance Cm1 of test coordinates by applying the first driving signal Tx1 to the first electrode ELt, sensing the second mutual capacitance Cm2 of the test coordinates by applying the second driving signal Tx2 to the first electrode ELt, and determining whether a touch operation is performed by detecting a difference between the first electrode ELt and the second mutual capacitance Cm2.

In an embodiment, the first driving signal Tx1 and the second driving signal Tx2 may be adjusted according to a degree of boosting of the charge pump CP. The charge pump CP may boost the input voltage V applied to the signal driving unit 51 to a first voltage and apply the first driving signal Tx1 to the first electrode ELt. The charge pump CP may boost the input voltage V applied to the signal driving unit 51 to a second voltage and apply the second driving signal Tx2 to the first electrode ELt. The first voltage corresponding to the first driving signal Tx1 and the second voltage corresponding to the second driving signal Tx2 may be determined according to a degree of boosting of the charge pump CP with respect to an input voltage V.

In summary, a method of testing a display apparatus, according to an embodiment, entails sensing the first mutual capacitance Cm1 when the charge pump CP boosts an input voltage V to a first voltage and applies the first driving signal Tx1 to the first electrode ELt, sensing the second mutual capacitance Cm2 when the charge pump CP boosts the input voltage V to a second voltage and applies the second driving signal Tx2 to the first electrode ELt, and determining whether a touch operation is performed by detecting a difference between the first mutual capacitance Cm1 and the second mutual capacitance Cm2. In an embodiment, the second voltage corresponding to the second driving signal Tx2 may be less than the first voltage corresponding to the first driving signal Tx1. As described above, when a touch operation is tested by using the charge pump CP built in the signal driving unit 51 instead of a direct touch of a touch object, the accuracy of the test may be improved and a time required for the test may be shortened.

FIG. 14A is a diagram showing that the first driving signal Tx1 is applied to some of driving electrode lines, and the second driving signal Tx2 is applied to other driving electrode lines. FIG. 14B shows Table 1 showing a size of mutual capacitance when the charge pump CP is used without a direct touch, and Table 2 showing a size of mutual capacitance in a case of direct hand touch. In FIG. 14B, the predetermined test coordinates are (REL2, TEL2).

Unlike FIG. 13, in which the first driving signal Tx1 and the second driving signal Tx2 are applied to one driving electrode line, FIG. 14A shows that the first driving signal Tx1 is applied to some of the driving electrode lines, and the second driving signal Tx2 is applied to some other driving electrode lines. Referring to FIG. 14A, the charge pump CP may apply the first driving signal Tx1 to some driving electrode lines by boosting the input voltage V received by the signal driving unit 51 to a first voltage, and apply the second driving signal Tx2 to some other driving electrode lines by boosting the input voltage V received by the signal driving unit 51 to a second voltage.

FIG. 14B shows tables showing sizes of mutual capacitance of a plurality of coordinates according to a plurality of driving electrode lines TEL0, TEL1, TEL2, TEL3, and TEL4 and a plurality of detection electrode lines REL0, REL1, REL2, REL3, and RELA. Table 1 is data obtained by applying, using the charge pump CP, the second driving signal Tx2 to the test driving electrode line TEL2 including the test coordinates (REL2, TEL2), and applying the first driving signal Tx1 to the other driving electrode lines TEL0, TEL1, TEL2, TEL3, and TELA. In Table 2 showing data in a case of hand touch, the value of the test coordinates (REL2, TEL2) is 1,546, and in Table 1 showing data obtained by using the charge pump CP, the value of the test coordinates (REL2, TEL2) is 1,515. It may be identified that the values of the test coordinates in Tables 1 and Table 2 are very similar to each other.

According to an embodiment described above, a method of testing a display apparatus to determine whether a touch detection device is operating normally may be performed without a direct touch of a contact object. However, the scope of the one or more embodiments is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of testing a display apparatus by using a touch sensor and a touch integrated circuit, wherein the touch sensor comprises a driving electrode line and a detection electrode line, and wherein the touch integrated circuit comprises a signal driving unit and a signal detection unit, the method comprising:
sensing a first mutual capacitance of predetermined test coordinates by applying a first driving signal to the driving electrode line and receiving a detection signal from the detection electrode line;
sensing a second mutual capacitance of the predetermined test coordinates by applying a second driving signal to the driving electrode line and receiving a detection signal from the detection electrode line; and
determining whether a touch operation is performed based on a difference between the first mutual capacitance and the second mutual capacitance.

2. The method of claim 1, further comprising selecting the second driving signal is so that the second mutual capacitance according to the second driving signal has a value corresponding to a mutual capacitance corresponding to a direct touch of a contact object.

3. The method of claim 1, wherein the signal driving unit comprises: a first switch and a second switch, which are selectively turned on and connect the signal driving unit and the driving electrode line to each other; and a test resistor connected to the driving electrode line by the second switch.

4. The method of claim 3, further comprising transferring a driving signal generated by the signal driving unit to the driving electrode line as the first driving signal if the first switch is turned on, and transferring the driving signal to the driving electrode line as the second driving signal if the second switch is turned on.

5. The method of claim 3, further comprising selecting a size of the test resistor so that the second mutual capacitance when the second switch is turned on has a value corresponding to a mutual capacitance when a contact object directly touches the display apparatus.

6. The method of claim 3, wherein the test resistor has a range of about 800Ω to about 1,200Ω.

7. The method of claim 1, wherein the signal driving unit comprises a charge pump configured to boost an input voltage and output the boosted voltage, and
the first driving signal and the second driving signal are adjusted according to a degree of boosting of the charge pump.

8. The method of claim 7, wherein a second voltage corresponding to the second driving signal is less than a first voltage corresponding to the first driving signal.

9. The method of claim 8, wherein each of the first voltage and the second voltage has a range of about 3 V to about 6 V.

10. The method of claim 1, wherein the driving electrode line comprises: driving electrodes arranged in a first direction; and first connection electrodes connecting the driving electrodes adjacent to each other in the first direction, and
the detection electrode line comprises: detection electrodes arranged in a second direction crossing the first direction; and second connection electrodes connecting detection electrodes adjacent to each other in the second direction.

11. The method of claim 10, wherein each of the first mutual capacitance and the second mutual capacitance is a capacitance between one of the first connection electrodes and one of the second connection electrodes that together define the predetermined test coordinates.

12. The method of claim 10, wherein the driving electrode line comprises a plurality of driving electrode lines arranged apart from each other in the second direction, and the detection electrode line comprises a plurality of detection electrode lines arranged apart from each other in the first direction.

13. A display apparatus comprising:
a touch sensor comprising a driving electrode line and a detection electrode line;
a touch integrated circuit comprising a signal driving unit and a signal detection unit, wherein the signal driving unit applies a driving signal to the driving electrode line, and the signal detection unit receives a detection signal from the detection electrode line;
a control unit that determines, through a variation in mutual capacitance between the driving electrode line and the detection electrode line, whether a touch is input;
a plurality of switches configured to be selectively turned on according to a control signal of the control unit and connect the driving signal to the driving electrode line; and
a test resistor connected to the driving electrode line by at least one of the plurality of switches,
wherein a size of the test resistor is selected so that a mutual capacitance generated when the test resistor is connected to the driving electrode line has a value corresponding to a mutual capacitance generated when a contact object directly touches the display apparatus.

14. The display apparatus of claim 13, wherein the plurality of switches are connected in parallel with each other.

15. The display apparatus of claim 13, wherein the test resistor has a range of about 800Ω to about 1,200Ω.

16. The display apparatus of claim 13, wherein the plurality of switches comprise a first switch and a second switch, the second switch connecting the test resistor to the driving electrode line.

17. The display apparatus of claim 13, wherein the driving electrode line comprises: driving electrode units arranged in a first direction; and first connection electrodes connecting the driving electrode units adjacent to each other in the first direction, and
the detection electrode line comprises: detection electrode units arranged in a second direction crossing the first direction; and second connection electrodes connecting detection electrode units adjacent to each other in the second direction.

18. The display apparatus of claim 17, wherein, in a plan view, each of the first connection electrodes has at least a portion overlapping one of the second connection electrodes.

19. The display apparatus of claim 17, wherein the driving electrode line comprises a plurality of driving electrode lines apart from each other in the second direction, and
the plurality of driving electrode lines are connected to the plurality of switches, respectively.

20. The display apparatus of claim 13, further comprising:
a driving signal line connecting the signal driving unit and the driving electrode line to each other; and
a detection signal line connecting the signal detection unit and the detection electrode line to each other.
